(19) United States
(12) Patent Application Publication
(10) Pub. No.: US 2026/0040510 A1
(43) Pub. Date: Feb. 5, 2026

(54) COOLING STRUCTURE

(71) Applicant: Panasonic Automotive Systems Co., Ltd., Kanagawa (JP)

(72) Inventor: Atsushi YAMASHIMA, Kanagawa (JP)

(73) Assignee: Panasonic Automotive Systems Co., Ltd., Kanagawa (JP)

(21) Appl. No.: 19/269,617

(22) Filed: Jul. 15, 2025

(30) Foreign Application Priority Data
Jul. 31, 2024 (JP) 2024-124740

(51) Int. Cl. H05K 7/20

(52) U.S. Cl. CPC H05K 7/20927

(57) ABSTRACT

A cooling structure includes a housing of a power conversion device, a flow path, and a heat transport member. The housing has a plurality of electronic components as a cooling target disposed therein. The flow path is disposed outside the housing and around the housing, and has a flow path interior through which a working fluid flows being spatially separated from an interior of the housing. The heat transport member is disposed from the interior of the housing to the flow path interior of the flow path, has a high-temperature portion thermally connected to each of the plurality of electronic components in the interior of the housing, and a low-temperature portion thermally connected to the working fluid in the flow path interior which is outside the housing, and forms a heat transport path which transports heat from each of the plurality of electronic components to the working fluid.

### CROSS-REFERENCE TO RELATED APPLICATIONS

This application is based upon and claims the benefit of priority from Japanese Patent Application No. 2024-124740, filed Jul. 31, 2024, the entire contents of which are incorporated herein by reference.

### FIELD

The present disclosure relates to a cooling structure.

### BACKGROUND

In recent years, in a power conversion device (power supply device) such as an in-vehicle charger or a DC-DC converter mounted on an electric vehicle (EV) or the like, a heat loss of a substrate-mounted component increases with an increase in output of a semiconductor, and thus there has been a problem in heat dissipation of the power conversion device. In addition, in an in-vehicle power supply device, a reduction in size has been required in anticipation of improvement in mountability with diversification of EVs, and a flow path of a cooling liquid for forced liquid cooling has been generally disposed in a housing interior of the power supply device.

For example, JP 2021-177676 A discloses a technique in which a power semiconductor module of a power conversion device is sandwiched between a pair of water channels (heat dissipation members), and heat is dissipated from the power semiconductor module to the pair of heat dissipation members via a pair of conductor members (heat pipes), thereby suppressing local hot spots and reducing the number of members that obstruct a heat dissipation path.

However, there has been a limit to the size reduction of the housing due to the arrangement of the flow path in the housing interior. In addition, in a case where a flow path of a working fluid for cooling is formed of die-cast, it is necessary to apply a sealing structure in order to suppress destruction of a substrate-mounted component (heat-generating component) due to leakage of the working fluid from a blowhole, and thus there has been a problem in that the size of a housing increases.

One of the problems to be solved by the present disclosure is to reduce the size of a cooling structure including a flow path of a working fluid for cooling.

### SUMMARY

A cooling structure according to the present disclosure includes a housing of a power conversion device, a flow path, and a heat transport member. The housing has a plurality of electronic components as a cooling target disposed therein. The flow path is disposed outside the housing and around the housing, and has a flow path interior through which a working fluid flows being spatially separated from an interior of the housing. The heat transport member is disposed from the interior of the housing to the flow path interior of the flow path. The heat transport member has a high-temperature portion and a low-temperature portion. The high-temperature portion is thermally connected to each of the plurality of electronic components in the interior of the housing. The low-temperature portion is thermally connected to the working fluid in the flow path interior which is outside the housing. The heat transport member forms a heat transport path which transports heat from each of the plurality of electronic components to the working fluid.

### BRIEF DESCRIPTION OF THE DRAWINGS

FIG. 1 is a perspective view illustrating an example of a configuration of a cooling structure according to an embodiment;

FIG. 2 is a perspective view illustrating an example of the configuration of the cooling structure in FIG. 1;

FIG. 3 is a cross-sectional view illustrating an example of the configuration of the cooling structure in FIG. 1;

FIG. 4 is a perspective view illustrating an example of a configuration of a heat pipe in FIG. 1;

FIG. 5 is a perspective view illustrating another example of the configuration of the cooling structure according to the embodiment;

FIG. 6 is a perspective view illustrating an example of the configuration of the cooling structure in FIG. 5;

FIG. 7 is a cross-sectional view illustrating an example of the configuration of the cooling structure in FIG. 5; and

FIG. 8 is a perspective view illustrating an example of a configuration of a heat pipe in FIG. 5.

### DETAILED DESCRIPTION

Embodiments of a cooling structure according to the present disclosure and a power conversion device and a vehicle to which the cooling structure is applied will be described below with reference to the drawings.

Note that, in the description of the present disclosure, components having the same or substantially the same functions as those described above with reference to previously described drawings are denoted by the same reference numerals, and description thereof may be omitted as appropriate. In addition, even in a case of representing the same or substantially the same portion, dimensions or ratios thereof may be represented differently from each other depending on the drawings. Further, for example, from the viewpoint of ensuring the visibility of the drawings, only main components are denoted by reference numerals in the description of each drawing, and even components having the same or substantially the same functions as those described above in previously described drawings may not be denoted by reference numerals.

Note that, in the description of the present disclosure, expressions such as orthogonal, horizontal, vertical, parallel, same, coincident, and same position are not limited to cases of strictly orthogonal, horizontal, vertical, parallel, same, coincident, and same position, but include cases that can be regarded as orthogonal, horizontal, vertical, parallel, same, coincident, and same position.

Note that the cooling structure according to the present disclosure can be applied to various power conversion devices. In each embodiment described below, a power supply device (in-vehicle charger) mounted on a vehicle (mobile body) such as an electric vehicle (EV) or a hybrid vehicle is illustrated as a power conversion device to which a cooling structure is applied. The in-vehicle charger may be, for example, a power conversion device that converts AC power supplied from a single-phase or three-phase AC power supply outside the vehicle into DC power and supplies the converted DC power to a load mounted on the vehicle. The load may be, for example, a battery, an inverter, a motor, various electrical components, or the like.

Note that the mobile body to which the cooling structure according to the present disclosure is applied may be, for example, a passenger car, a freight car, a shared car, a motorcycle, an electric kick scooter, a construction machine, an agricultural machine, an aircraft, and the like. In addition, the electrical components of the mobile body may be, for example, a navigation device, an audio device, an air conditioner, a power window, a defogger, an electronic control unit (ECU), a global positioning system (GPS) module, a camera, and the like. In addition, the battery of the mobile body may only be able to store electric power for driving a moving motor (main motor), an electrical component, or the like mounted on the mobile body, and for example, any battery such as a lithium ion battery, a nickel-hydrogen battery, or an all-solid-state battery can be appropriately used.

Note that a cooling (heat dissipation) target of the cooling structure according to the present disclosure is, for example, a heat-generating electronic component (heat-generating component) that is mounted on the power conversion device, but is not limited thereto. In addition to or instead of the heat-generating component, the cooling target may be a component that is heated by heat from the heat-generating component, or may be a component that forms a part of a heat transport path from the heat-generating component.

Note that the cooling structure according to the present disclosure may be applied to a heat-generating unit (cooling target) of a mobile body other than the charger. The heat-generating unit of the vehicle may be, for example, an in-vehicle device constituted by a plurality of electronic components including a power semiconductor and/or a magnetic component. As an example, the heat-generating unit of the vehicle may be a power conversion device (DC-DC converter) that is constituted by a plurality of electronic components including a magnetic component, converts input DC power into DC power having a predetermined voltage value, and outputs the converted DC power. Note that the power conversion device including at least the magnetic component may be referred to as a coil device. In addition, the heat-generating unit of the vehicle may be, for example, another in-vehicle device such as a battery or an electrical component.

Note that the cooling structure according to the present disclosure is not limited to the power conversion device mounted on the mobile body, and may be applied to a power conversion device mounted on another device of the mobile body or installed outside the mobile body, such as a charging device of a charging station, amusement equipment, or an uninterruptible power supply device, for example.

A power conversion device to which a cooling structure according to the present disclosure is applied is cooled by using, for example, a cooling system of a forced liquid cooling type. The cooling system is a system that is applied to, for example, a vehicle (mobile body) and configured to be able to cool the heat-generating unit of the vehicle. As an example, in the cooling system, a cooling liquid (working fluid) for forced liquid cooling circulates and transports heat from the power conversion device to outside the power conversion device. A cooling liquid used for cooling a battery, a motor, an engine, or the like in a vehicle (mobile body) may be used as the cooling liquid. Alternatively, the cooling system may share a radiator mounted on the vehicle (mobile body) with another cooling system.

Note that the cooling system of the power conversion device is, for example, a liquid cooling type that uses a cooling liquid as a working fluid, but may be a system that cools the power conversion device by a cooling type other than the liquid cooling type such as an air cooling type or a phase-change cooling type. In other words, the cooling system of the power conversion device may be a system using any refrigerant as a working fluid. In addition, the cooling system of the power conversion device may be configured as a part of an air conditioning system, for example, and may use a refrigerant circulating in the air conditioning system as the working fluid. In this case, the cooling structure according to the present disclosure may be connected to, for example, an outlet of an evaporator of the air conditioning system, and may be supplied with a refrigerant from the evaporator. In addition, the cooling structure according to the present disclosure may be connected to, for example, an inlet of a compressor of the air conditioning system, and may discharge a refrigerant that has passed through the interior of the cooling structure and supply the refrigerant to the compressor.

### FIRST EMBODIMENT

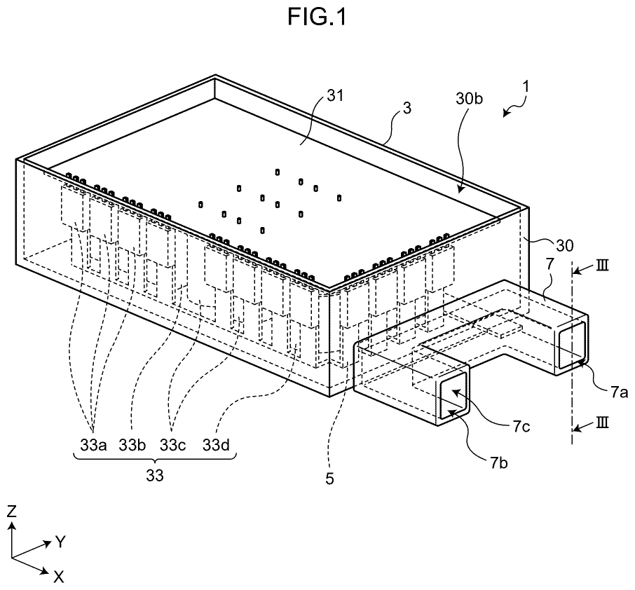

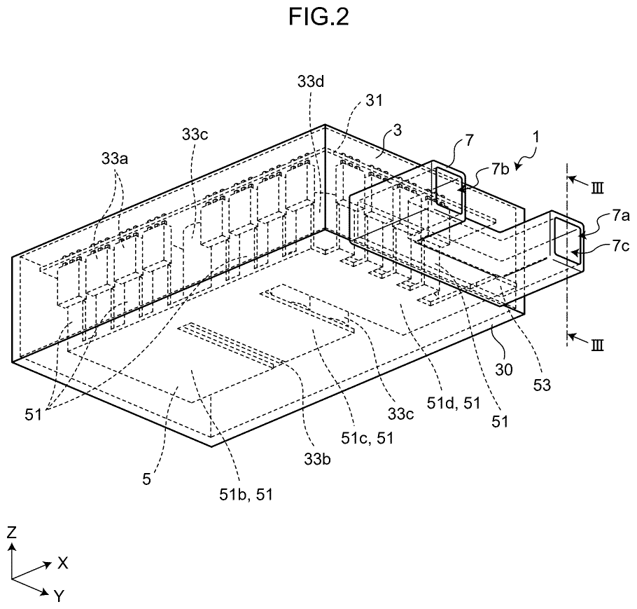

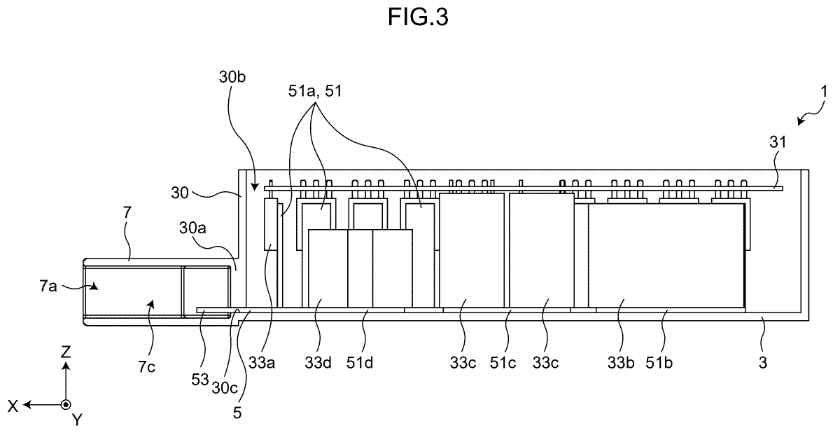

FIGS. 1 and 2 are perspective views each illustrating an example of a configuration of a cooling structure 1 according to the present embodiment. FIG. 1 illustrates a state where the cooling structure 1 is viewed from above (+Z side). FIG. 2 illustrates a state where the cooling structure 1 is viewed from below (−Z side). FIG. 3 is a cross-sectional view illustrating an example of the configuration of the cooling structure 1 in FIG. 1. FIG. 3 illustrates a Z-X cross-section viewed from the +Y side as indicated by III-III in FIGS. 1 and 2.

As illustrated in FIGS. 1 to 3, the cooling structure 1 according to the present embodiment is applied to a power supply device 3. The power supply device 3 is mounted with a plurality of electronic components including a heat-generating component to be heat dissipated (cooled). Here, the power supply device 3 according to the embodiment is an example of a power conversion device constituted by a plurality of electronic components including a power semiconductor and/or a magnetic component. The power supply device 3 can be realized as, for example, an in-vehicle charger mounted on a vehicle (mobile body).

As illustrated in FIGS. 1 to 3, the power supply device 3 has a housing 30. The housing 30 is a box-shaped member formed of a metal material such as die-cast. In other words, the housing 30 is formed of a material having thermal conductivity, and may form a part of a heat transfer path that transports heat of an electronic component as a cooling target to a working fluid such as a cooling liquid.

Note that, in the example illustrated in FIGS. 1 to 3, the upper side (+Z side) of the housing 30 is open, but the example is not limited thereto. For example, a lid-shaped member which is not illustrated may be provided on the upper side (+Z side) of the housing 30. The lid-shaped member is not limited to the upper side (+Z side) of the housing 30, and may be provided on any of the sides (−X side, +Y side, −Y side, and −Z side) on which a flow path 7 of the housing 30 is not provided. Alternatively, some or all of the sides (−X side, +Y side, −Y side, and −Z side) of the housing 30 on which the flow path 7 is not provided may be open.

A plurality of substrate-mounted components 33 mounted on a substrate 31 is provided in a housing interior 30b, which is the internal space of the housing 30. The plurality of substrate-mounted components 33 is an example of a plurality of electronic components including semiconductor and/or magnetic components. For example, in the example of FIGS. 1 to 3, the substrate-mounted components 33 disposed in the housing interior 30b of the power supply device 3 include a MOSFET 33a (power semiconductor), a transformer 33b, an electrolytic capacitor 33c, and a choke coil 33d. Note that FIGS. 1 to 3 illustrate a case where the choke coil 33d is potted in the casing.

Note that some or all of the plurality of electronic components of the power supply device 3 may be electrically connected via a bus bar or the like, that is, not via the substrate 31. In other words, some or all of the plurality of electronic components of the power supply device 3 may not be configured as substrate-mounted components. Similarly, in the power supply device 3, the substrate 31 is not an essential component and may not be provided.

For example, the power supply device 3 may be provided with a noise filter that suppresses (removes) entry of noise from an external AC power supply to the power supply device 3 and outflow of noise from the power supply device 3 to the AC power supply. In addition, for example, a power conversion circuit that converts AC power supplied from an external single-phase or three-phase AC power supply via the noise filter into DC power and outputs the converted DC power to a battery is provided in a stage subsequent to the noise filter. The power conversion circuit is provided with, for example, a power factor correction (PFC) circuit that rectifies and smooths an AC voltage from an external AC power source after noise is removed by the noise filter to generate a DC voltage. In addition, for example, in the power conversion circuit, a DC-DC conversion circuit (DC-DC converter) that generates a DC voltage of an arbitrary set voltage by converting the DC voltage generated by the PFC circuit into an AC voltage again and then rectifying and smoothing the DC voltage is provided at a subsequent stage of the PFC circuit.

For example, substrate-mounted components 33 (heat-generating components) such as the MOSFET 33a (power semiconductor) and the electrolytic capacitor 33c are included in each unit of the in-vehicle charger such as the PFC circuit and the DC-DC conversion circuit. These substrate-mounted components 33 generate a large amount of heat when power conversion is performed on large-current or high-voltage power. Such substrate-mounted component 33 is an example of a cooling target by the cooling structure 1 according to the present disclosure, and is also an example of a heat-generating unit of the vehicle.

For example, electronic components such as the electrolytic capacitor 33c having a strong correlation between temperature and lifetime are included in each unit of the in-vehicle charger such as the PFC circuit and the DC-DC conversion circuit. The upper limit of the operating temperature of these electronic components may be set to be lower than the maximum operating temperature specified by the specifications of the components. Such electronic components are also examples of cooling targets by the cooling structure 1 according to the present disclosure.

In addition, various inductors such as the transformer 33b, a transformer integrated printed board, and the choke coil 33d, a reactor, or magnetic components such as an assembly including these components are included in each unit of the in-vehicle charger such as the noise filter, the PFC circuit, and the DC-DC conversion circuit. The coil device mounted with the magnetic component such as the in-vehicle charger, the noise filter, the PFC circuit, or the DC-DC conversion circuit (DC-DC converter) generates a large amount of heat when power conversion is performed on large-current or high-voltage power. Such coil device or magnetic component of the coil device is an example of a cooling target by the cooling structure 1 according to the present disclosure, and is also an example of the heat-generating unit of a vehicle.

As illustrated in FIGS. 1 to 3, the cooling structure 1 according to the present embodiment further has the flow path 7.

The flow path 7 is an example of a pipe line through which a working fluid (cooling liquid) circulating in a cooling system for forced liquid cooling of the power supply device 3 flows. Note that the cooling system of the power supply device 3 may be another cooling system of a liquid cooling type such as an air cooling type, and the flow path 7 may be a flow path through which a gas (working fluid) such as air flows. The flow path 7 is formed of, for example, a metal material such as die-cast, but may be formed of a non-metal material such as resin. The flow path 7 is formed of, for example, a hollow pipe line. Note that the cross-sectional shape of the pipe line forming the flow path 7 may be any shape, and may be a circular shape or an elliptical shape, or may be a polygonal shape such as a rectangular shape. In the flow path 7, the cooling liquid is supplied from an inflow portion 7a to a flow path interior 7c of the flow path. In addition, the cooling liquid that has flowed through the flow path interior 7c is discharged from the outflow portion 7b to outside the flow path 7.

As an example, the flow path 7 is disposed, for example, outside the housing 30 of the power supply device 3, adjacent to the housing 30. In other words, the flow path 7 side of the housing 30 and the housing 30 side of the flow path 7 are adjacent and in physically contact with (adjacent to) each other. On the other hand, the flow path interior 7c, which is a space inside the flow path of the flow path 7, is spatially separated from the housing interior 30b of the power supply device 3.

As an example, as illustrated in FIG. 3, the housing interior 30b of the power supply device 3 and the flow path interior 7c are disposed via a partition wall portion 30a and are spatially separated from each other. Here, the partition wall portion 30a spatially partitions the housing interior 30b of the power supply device 3 and the flow path interior 7c, and may be shared between the housing 30 and the flow path 7, or may be separately provided. For example, the partition wall portion 30a may be formed by a part of the housing 30 of the power supply device 3, may be formed by a part of a member forming the flow path 7, or may be formed by both of these parts.

As an example, in the cooling structure 1 according to the present embodiment, the flow path 7 does not overlap the housing 30 of the power supply device 3 in a plan view. Specifically, the flow path 7 does not overlap the housing 30 when the X-Y plane is viewed from +Z side or −Z side. In other words, the positions of the flow path 7 and the housing 30 in the X-Y plane are different from each other.

As illustrated in FIGS. 1 to 3, the cooling structure 1 according to the present embodiment further has a heat pipe 5.

The heat pipe 5 is an example of a heat transport member that collects heat from the substrate-mounted component 33 in the housing interior 30b of the power supply device 3 and transports the heat to the space outside the housing 30. The heat pipe 5 is a flat plate-shaped hollow member formed of, for example, a metal material such as copper, aluminum, or an alloy thereof, and a refrigerant is sealed inside the heat pipe. Note that the heat pipe 5 according to the embodiment is, for example, a thin heat pipe formed in a thin flat plate shape, but the shape thereof may be appropriately determined according to the shape and arrangement of the electronic component as a cooling target, and a part or the whole thereof may be formed in a tubular shape.

As illustrated in FIGS. 1 to 3, the heat pipe 5 is disposed from the housing interior 30b of the power supply device 3 to the flow path interior 7c (inside the flow path) of the flow path 7. Specifically, the heat pipe 5 is disposed so as to penetrate, at a penetration portion 30c, the partition wall portion 30a that spatially separates the housing interior 30b of the power supply device 3 and the flow path interior 7c of the flow path 7. As an example, the heat pipe 5 is inserted into the penetration portion 30c from the housing interior 30b of the power supply device 3. In other words, a part of the heat pipe 5 according to the embodiment protrudes to outside the housing 30 from the housing interior 30b of the power supply device 3 toward the inflow portion 7a side of the flow path interior 7c of the flow path 7.

The heat pipe 5 forms a heat transport path through which heat from each of the plurality of substrate-mounted components 33 (electronic components) as a cooling target is transported to the cooling liquid flowing through the flow path interior 7c of the flow path 7. Specifically, the heat pipe 5 is thermally connected, in the housing interior 30b of the power supply device 3, to the plurality of substrate-mounted components 33 (electronic components) as a cooling target. In addition, the heat pipe 5 is thermally connected to the flow path interior 7c of the flow path 7. In other words, the heat pipes 5 is thermally connected to the cooling liquid flowing through the flow path interior 7c of the flow path 7. Therefore, the heat pipe 5 collects, in the housing interior 30b of the power supply device 3, heat from the plurality of substrate-mounted components 33 as a cooling target, and transports the heat to the outside (the flow path 7) of the housing 30 of the power supply device 3.

Here, in the present disclosure, “A” and “B” being thermally connected to each other means that heat can be exchanged between “A” and “B”. Note that, in the present disclosure, “thermal connection” is realized by, for example, a heat transport mode of heat conduction, but may be realized by another heat transport mode in addition to or instead of heat conduction. In addition, in the present disclosure, “thermal connection” may be realized by a heat transport path via another element such as a heat diffusion sheet, a heat diffusion plate, a heat conductive grease, a heat conductive adhesive, a filler such as a potting material, or another electronic component, for example.

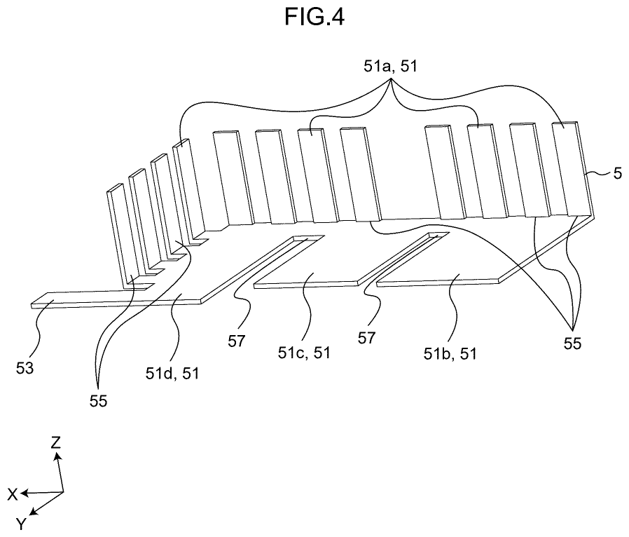

FIG. 4 is a perspective view illustrating an example of the configuration of the heat pipe 5 in FIG. 1. As illustrated in FIGS. 1 to 4, the heat pipe 5 has a high-temperature portion 51 and a low-temperature portion 53.

The high-temperature portion 51 is a portion of the heat pipe 5 disposed in the housing interior 30b of the power supply device 3. In other words, the high-temperature portion 51 is a part of the heat pipe 5, and is a portion located on the side of the housing interior 30b of the power supply device 3 with respect to the partition wall portion 30a in a state where the heat pipe 5 is assembled to the housing 30 of the power supply device 3.

The high-temperature portion 51 is thermally connected to, in the housing interior 30b, each of the plurality of substrate-mounted components 33 (electronic components) as a cooling target. In other words, the high-temperature portion 51 diffuses and collects, in the housing interior 30b, heat from each of the plurality of substrate-mounted components 33 as a cooling target.

The high-temperature portion 51 has a main portion extending from the low-temperature portion 53. The main portion of the high-temperature portion 51 is formed in a flat plate shape. The main portion of the high-temperature portion 51 extends along the X-Y plane to the −X side in a state where the main surface of the low-temperature portion 53 is disposed along the X-Y plane.

The high-temperature portion 51 has a plurality of first high-temperature portions 51a, a second high-temperature portion 51b, a third high-temperature portion 51c, and a fourth high-temperature portion 51d.

Each of the plurality of first high-temperature portions 51a is formed in a flat plate shape. In addition, each of the plurality of first high-temperature portions 51a extends from an end portion of the main portion of the high-temperature portion 51 in a direction away from the main surface of the main portion. Each of the plurality of first high-temperature portions 51a extends in the Z direction from each of the end portion on the +X side and the end portion on the −x side of the main portion in a state where the main surface of the main portion of the high-temperature portion 51 is disposed along the X-Y plane. As illustrated in FIGS. 1 to 3, the plurality of first high-temperature portions 51a is thermally connected to the heat dissipation surfaces of the plurality of MOSFETs 33a, respectively.

As an example, each of the plurality of first high-temperature portions 51a is formed by bending a part of a plurality of convex portions extending from the end portion of the main portion of the high-temperature portion 51 along the main surface thereof to form a bent portion 55. Note that one convex portion of the plurality of convex portions may be formed as the low-temperature portion 53.

Each of the second high-temperature portion 51b, the third high-temperature portion 51c, and the fourth high-temperature portion 51d is provided in the main portion of the high-temperature portion 51. In other words, each of the second high-temperature portion 51b, the third high-temperature portion 51c, and the fourth high-temperature portion 51d is formed in a flat plate shape.

The second high-temperature portion 51b extends in the −X direction from the third high-temperature portion 51c. A cutout portion 57 is provided between the second high-temperature portion 51b and the third high-temperature portion 51c, and a width (a length in the Y direction) of each of the second high-temperature portion 51b and the third high-temperature portion 51c is longer than a width (a length in the Y direction) of a connection portion between the second high-temperature portion 51b and the third high-temperature portion 51c. As illustrated in FIGS. 1 to 3, the second high-temperature portion 51b is thermally connected to the heat dissipation surface of the transformer 33b.

The third high-temperature portion 51c extends in the −X direction from the fourth high-temperature portion 51d. A cutout portion 57 is provided between the third high-temperature portion 51c and the fourth high-temperature portion 51d, and a width (a length in the Y direction) of each of the third high-temperature portion 51c and the fourth high-temperature portion 51d is longer than a width (a length in the Y direction) of a connection portion between the third high-temperature portion 51c and the fourth high-temperature portion 51d. As illustrated in FIGS. 1 to 3, the third high-temperature portion 51c is thermally connected to the heat dissipation surface of the electrolytic capacitor 33c.

The fourth high-temperature portion 51d extends in the −X direction from the low-temperature portion 53. As illustrated in FIGS. 1 to 3, the fourth high-temperature portion 51d is thermally connected to the heat dissipation surface of the choke coil 33d.

Note that the cutout portion 57 is not an essential component and may not be provided.

The low-temperature portion 53 is a portion of the heat pipe 5 that is disposed outside the housing 30 of the power supply device 3 and in the flow path interior 7c of the flow path 7. In other words, the low-temperature portion 53 is a part of the heat pipe 5, and is a portion located on the side (the outer side of the power supply device 3) of the flow path 7 with respect to the partition wall portion 30a in a state where the heat pipe 5 is assembled to the housing 30 of the power supply device 3. Specifically, the low-temperature portion 53 is a portion that protrudes from the housing interior 30b of the power supply device 3 to the flow path interior 7c on the side of the inflow portion 7a of the flow path 7 in a state where the heat pipe 5 is assembled to the housing 30 of the power supply device 3.

The low-temperature portion 53 is thermally connected to the flow path interior 7c of the flow path 7. In other words, the low-temperature portion 53 is thermally connected to the cooling liquid flowing through the flow path interior 7c of the flow path 7 in the flow path interior 7c of the flow path 7. In other words, the low-temperature portion 53 is cooled by the cooling liquid flowing through the flow path interior 7c of the flow path 7, and is in a relatively low-temperature state with respect to the high-temperature portion 51. Therefore, the heat collected from each of the plurality of substrate-mounted components 33 as a cooling target is transported to the low-temperature portion 53. In addition, the low-temperature portion 53 discharges (dissipates) heat from each of the plurality of substrate-mounted components 33 as a cooling target to the cooling liquid by heat exchange with the cooling liquid.

The low-temperature portion 53 is formed in a flat plate shape and extends from the high-temperature portion 51. The main portion of the low-temperature portion 53 extends in the +X direction along the X-Y plane in a state where the main surface of the main portion of the high-temperature portion 51 is disposed along the X-Y plane.

More specifically, as illustrated in FIG. 3, the low-temperature portion 53 penetrates the penetration portion 30c of the partition wall portion 30a to extend from the high-temperature portion 51 to the flow path interior 7c in a state where the heat pipe 5 is assembled to the housing 30 of the power supply device 3. In the penetration portion 30c, a seal member (not illustrated) is provided, between the heat pipe 5 and the partition wall portion 30a, to suppress leakage of the cooling liquid from the flow path 7 to the housing interior 30b of the power supply device 3. On the other hand, the housing 30 does not have a connection portion spatially connected to the flow path 7 other than the penetration portion 30c. As described above, in the cooling structure 1 according to the present disclosure, the connection portion between the housing interior 30b of the power supply device 3 and the flow path 7 is only the penetration portion 30c. In other words, in the cooling structure 1, the sealing structure that suppresses the leakage of the cooling liquid from the flow path 7 to the housing interior 30b of the power supply device 3 may be applied to at least the penetration portion 30c.

As described above, in the cooling structure 1 according to the present embodiment, the flow path 7 of the cooling liquid for forced liquid cooling is disposed adjacent to the housing 30 outside the housing 30 of the power supply device 3 (power conversion device) on which the plurality of substrate-mounted components 33 (electronic components) as a cooling target are mounted, and the flow path interior 7c of the flow path is spatially separated from the housing interior 30b of the power supply device 3. In addition, in the cooling structure 1 according to the present embodiment, the heat transport path is formed, by the heat pipe 5 disposed from the housing interior 30b to the flow path interior 7c, which transports heat from each of the plurality of substrate-mounted components 33 to the cooling liquid flowing through the flow path interior 7c.

Conventionally, in the power supply device (power conversion device), a heat loss of a substrate-mounted component increases with an increase in output of a semiconductor, for example, and thus there has been a problem in heat dissipation of the power supply device. In addition, the in-vehicle power supply device has been required to be reduced in size in anticipation of improvement in mountability with diversification of EVs. For example, in a case where power conversion is performed on large-current or high-voltage power, as the control frequency of the power conversion increases, a reduction in size progresses, but heat dissipation from a heat-generating component has been a problem.

Therefore, a flow path of a cooling liquid for forced liquid cooling has been generally disposed in the housing interior. However, there has been a problem that the size reduction of the housing is limited due to the arrangement of the flow path in the housing interior. In addition, in a case where the flow path of the working fluid for cooling is formed of die-cast, it is necessary to apply a massive or large-scale sealing structure in order to suppress a fatal market defect such as destruction of an electronic component due to leakage of the working fluid from a blowhole, and thus there has been a problem in that the size of the housing increases. In other words, there has been a room for improvement in reduction of the size of the cooling structure including the flow path of the working fluid for cooling.

In addition, in a case where the flow path is disposed in the housing interior, there has been a problem in that the layout of components in the housing interior is limited, for example, the cooling surface (heat dissipation surface) depends on the routing (layout) of the flow path. For example, conventionally, there has been a case where a flow path of a cooling liquid is formed inside a die-cast housing and a heat-generating component is assembled to the housing, so that the heat-generating component is cooled by being thermally connected to the housing directly or indirectly via another component or member. In other words, there has been a room for improvement in the construction of the heat transport path from the heat-generating component to the flow path (cooling mechanism).

Under such circumstances, in the cooling structure 1 according to the present embodiment, the flow path 7 is not provided in the housing interior 30b of the power supply device 3. As described above, the cooling structure 1 according to the present embodiment is configured to collect and transport heat from each of the plurality of substrate-mounted components 33 to the flow path 7 outside the housing 30 spatially separated from the housing interior 30b by routing the heat pipe 5 (heat transport member).

Therefore, according to the cooling structure 1 according to the present embodiment, a space for disposing the flow path 7 is not required in the housing interior 30b. In addition, it is not necessary to route the flow path 7 in the housing interior 30b. Therefore, it is possible to suppress an increase in size due to the arrangement of the flow path 7 in the housing interior 30b and to realize a reduction in size of the power supply device 3. In addition, the cooling structure 1 according to the present embodiment can be mounted on a mobile body such as a vehicle without disposing the flow path 7 of the cooling liquid in the housing interior 30b of the power supply device 3. Therefore, it is possible to reduce the risk of destruction of the power supply device 3 in the market due to liquid leakage from the flow path 7. In addition, according to the cooling structure 1 according to the present embodiment, since the flow path 7 is provided outside the housing 30 of the power supply device 3, it is possible to alleviate the limitation of the component layout due to the arrangement of the flow path 7 in the housing interior 30b.

In addition, in the cooling structure 1 according to the present embodiment, the housing 30 of the power supply device 3 does not have a connection portion spatially connected to the flow path 7 other than the penetration portion 30c through which the heat pipe 5 penetrates. Thus, a sealing structure can be realized by the sealing member disposed in the penetration portion 30c. In other words, according to the cooling structure 1 according to the present embodiment, it is not necessary to apply a large-scale sealing structure, and it is possible to suppress an increase in size due to the application of the sealing structure and realize a reduction in the size of the power supply device 3.

In addition, since the heat transport path is formed via the heat pipe 5, the position at which the low-temperature portion 53 protrudes from the housing 30 can be changed as appropriate. In other words, it is possible to improve the degree of freedom of arrangement of the flow path 7 with respect to the housing 30.

Other embodiments and modifications of the cooling structure 1 according to the present disclosure will be described below with reference to the drawings. Note that, in the following description, differences from the above-described embodiment will be mainly described, and redundant description will be omitted as appropriate.

### SECOND EMBODIMENT

In the above-described embodiment, the cooling structure 1 in which the housing 30 is formed of a metal material such as die-cast has been illustrated, but the embodiment is not limited thereto.

For example, in the cooling structure 1 according to the present embodiment, the housing 30 may be formed of a material other than a material having thermal conductivity (heat transfer body). For example, the housing 30 may be formed of a material having no thermal conductivity.

As an example, the housing 30 may be formed of a non-metal material such as resin.

For example, an electromagnetic shield layer is formed on the outer surface or the inner surface of the housing 30. The electromagnetic shield layer may be formed so as to cover the electronic components disposed in the housing interior 30b, and may be provided in addition to the outer surface and the inner surface of the housing 30. The electromagnetic shield layer may be formed to such an extent that an electromagnetic shield effect is obtained with respect to the electronic components disposed in the housing interior 30b.

Note that the electromagnetic shield layer may be a layer of a metal material formed on an outer surface or an inner surface thereof by, for example, plating or sputtering. Alternatively, the electromagnetic shield layer may be realized by a metal thin film attached to the outer surface or the inner surface thereof. Alternatively, the electromagnetic shield layer may be formed by applying a coating material containing a metal material to the outer surface or the inner surface thereof.

As described above, in the cooling structure 1 according to the present embodiment, since the housing 30 is formed using a non-metal material, it is possible to reduce the risk of occurrence of blowholes as in die-cast, that is, to suppress the entry of the cooling liquid into the housing interior 30b, and to reduce the risk of destruction of the power supply device 3 due to liquid leakage from the flow path 7. In addition, the degree of freedom of material selection is improved, and cost reduction and weight reduction can be realized.

### THIRD EMBODIMENT

In the above-described embodiment, the cooling structure 1 configured to be able to simultaneously cool (dissipate heat from) the plurality of types of substrate-mounted components 33 has been illustrated, but the embodiment is not limited thereto.

For example, in the cooling structure 1 according to the present embodiment, the heat pipe 5 may be configured to be able to locally cool (dissipate heat from) the power supply device 3, such as targeting only some substrate-mounted components 33. In the present embodiment, a description will be given below of the cooling structure 1 in which only the MOSFET 33a is a cooling target that draws heat away to the flow path 7 by the heat pipe 5.

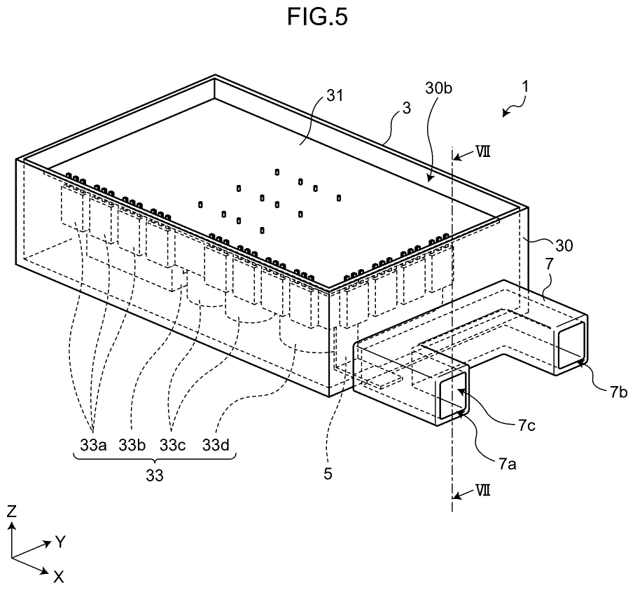

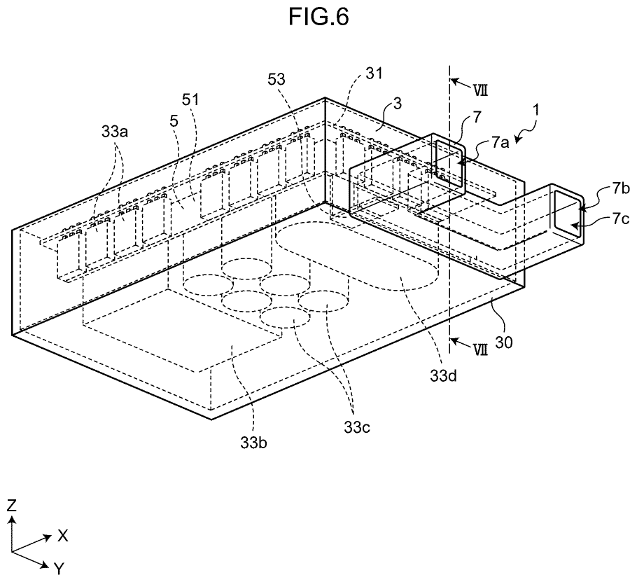

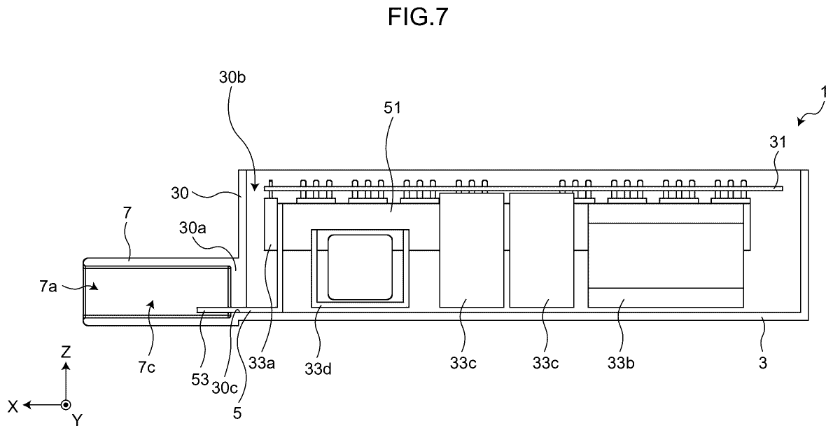

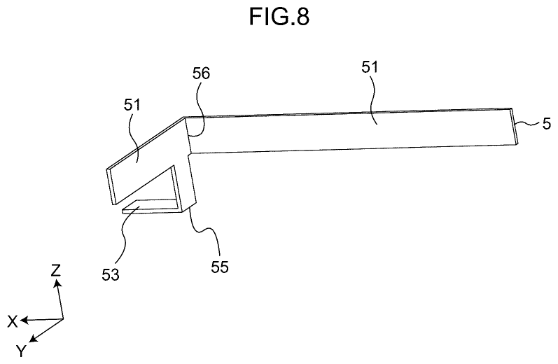

FIGS. 5 and 6 are perspective views illustrating another example of the configuration of the cooling structure 1 according to the embodiment. FIG. 5 illustrates a state where the cooling structure 1 is viewed from above (+Z side) as in FIG. 1. FIG. 6 illustrates a state where the cooling structure 1 is viewed from below (−Z side) as in FIG. 2. FIG. 7 is a cross-sectional view illustrating an example of the configuration of the cooling structure 1 in FIG. 5. FIG. 7 illustrates a Z-X cross-section viewed from the +Y side as indicated by VII-VII in FIGS. 5 and 6. FIG. 8 is a perspective view illustrating an example of the configuration of the heat pipe 5 in FIG. 5.

As illustrated in FIGS. 5 to 8, the high-temperature portion 51 of the heat pipe according to the present embodiment corresponds to one in which the plurality of first high-temperature portions 51a according to the first embodiment is integrated as one high-temperature portion.

Specifically, the high-temperature portion 51 according to the present embodiment is thermally connected to, in the housing interior 30b, each of the plurality of MOSFETs 33a as a cooling target. In other words, the high-temperature portion 51 diffuses and collects, in the housing interior 30b, heat from each of the plurality of MOSFETs 33a as a cooling target.

The high-temperature portion 51 has a connection portion extending from the low-temperature portion 53. The connection portion of the high-temperature portion 51 is formed in a flat plate shape. The connection portion of the high-temperature portion 51 extends along the X-Y plane to the −X side in a state where the main surface of the low-temperature portion 53 is disposed along the X-Y plane.

As an example, the high-temperature portion 51 is formed by bending a flat plate-shaped portion extending from an end portion of a connection portion with the low-temperature portion 53 along a main surface thereof to form the bent portion 55. In other words, the high-temperature portion 51 according to the present embodiment extends in the Z direction similarly to the first high-temperature portion 51a according to the above-described embodiment.

In addition, the high-temperature portion 51 formed by bending at the bent portion 55 extends to the +Y side along, for example, the arrangement of the MOSFETs 33a, and extends to the −X side by further bending a part thereof to form a bent portion 56. In other words, the high-temperature portion 51 according to the present embodiment includes a flat plate-shaped portion extending along the Y-Z plane and a flat plate-shaped portion extending along the Z-X plane.

As described above, the flat plate-shaped portion extending along the Y-Z plane of the high-temperature portion 51 according to the present embodiment has a shape in which only the connection portion with the heat dissipation surface of the MOSFET 33a and the vicinity thereof are integrated along the X direction with respect to some first high-temperature portions 51a extending in the Z direction from the end portion on the +X side of the main portion of the high-temperature portion 51 among the plurality of first high-temperature portions 51a according to the above-described embodiment. Similarly, the flat plate-shaped portion extending along the Z-X plane of the high-temperature portion 51 according to the present embodiment has a shape in which only the connection portion with the heat dissipation surface of the MOSFET 33a and the vicinity thereof are integrated along the X direction with respect to some first high-temperature portions 51a extending in the Z direction from the end portion on the −Y side of the main portion of the high-temperature portion 51 among the plurality of first high-temperature portions 51a according to the above-described embodiment.

Even this configuration can obtain the same effects as those of the above-described embodiment. In addition, by adopting the shape of the heat pipe 5 according to a desired cooling target, it is possible to realize further size reduction, improvement in the degree of freedom of layout, and weight reduction.

Note that the technique according to the present embodiment can be appropriately combined with at least one of Ser. No. 11/114,325.1 the first and second embodiments.

### FOURTH EMBODIMENT

Note that, in each of the above-described embodiments, the cooling structure 1 in which the flow path 7 and the housing 30 are disposed at positions different from each other in a plan view has been illustrated, but the embodiment is not limited thereto.

The interiors of the flow path 7 and the housing 30 may be spatially separated from each other, or may be disposed to overlap each other in a plan view.

As an example, the flow path 7 is not limited to the sideward of the housing 30, and may be provided below (−Z side) the housing. In this case, the low-temperature portion 53 may extend downward to protrude to outside the housing 30 by being bent or the like, and may be thermally connected to the flow path interior 7c.

As an example, the housing 30 may have a shape that is recessed toward the housing interior 30b or a shape that is hollowed out so as to allow a duct to pass therethrough, with respect to a dead space in which no component or the like is disposed in the housing interior 30b. In addition, the flow path 7 may be disposed in a space formed outside the housing 30 by recessing inward or hollowing out the housing 30. In this case, the low-temperature portion 53 may extend toward the flow path 7 to protrude to outside the housing 30 by being bent or like according to the positional relationship with the flow path 7, and may be thermally connected to the flow path interior 7c.

As an example, a gap may be provided between the housing 30 and the flow path 7. In other words, the housing 30 and the flow path 7 may share a part thereof or may have outer surfaces in contact with each other, or may be disposed at positions spatially separated from each other.

Even these configurations can obtain the same effects as those of the above-described embodiment. In addition, since the heat transport path is formed via the heat pipe 5, even if the flow path 7 is configured to be provided below the housing 30 of the power supply device 3, configured to be provided in a recessed or hollowed-out portion of the housing 30, or configured to be spatially separated from the housing 30, the low-temperature portion 53 may protrude from the corresponding position in the corresponding direction. In other words, even in a case where the flow path 7 and the housing 30 are disposed to overlap each other in a plan view, it is not necessary to route the flow path in accordance with the arrangement of the electronic components as cooling targets, and it is possible to suppress an increase in size due to the routing.

According to at least one of the embodiments described above, it is possible to reduce the size of the cooling structure including the flow path of the working fluid for cooling.

According to the present disclosure, it is possible to reduce the size of a cooling structure including a flow path of a working fluid for cooling. Note that the effects described herein are not necessarily limited, and may be any of the effects described herein.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A cooling structure comprising:
a housing of a power conversion device having a plurality of electronic components as a cooling target disposed therein;
a flow path disposed outside the housing and around the housing, and having a flow path interior through which a working fluid flows being spatially separated from an interior of the housing; and
a heat transport member which is disposed from the interior of the housing to the flow path interior of the flow path, has a high-temperature portion which is thermally connected to each of the plurality of electronic components in the interior of the housing and a low-temperature portion which is thermally connected to the working fluid in the flow path interior which is outside the housing, and forms a heat transport path which transports heat from each of the plurality of electronic components to the working fluid.

2. The cooling structure according to claim 1, wherein
the housing is formed of a metal material.

3. The cooling structure according to claim 1, wherein
the housing is formed of a non-metal material.

4. The cooling structure according to claim 3, wherein
an electromagnetic shield layer is formed on an outer surface or an inner surface of the housing.

5. The cooling structure according to claim 1, wherein
the low-temperature portion extends from the high-temperature portion to protrude to outside the housing from a penetration portion provided in the housing.

6. The cooling structure according to claim 5, wherein
the low-temperature portion extends to the flow path interior outside the housing via the penetration portion.

7. The cooling structure according to claim 5, further comprising
a sealing member disposed in the penetration portion.

8. The cooling structure according to claim 5, wherein
a side of the flow path closer to the housing and a side of the housing closer to the flow path are adjacent to each other, and
the housing does not have a connection portion spatially connected to the flow path, other than the penetration portion.

9. The cooling structure according to claim 5, wherein
the penetration portion is provided in a partition wall portion shared by the housing and the flow path.

10. The cooling structure according to claim 5, wherein
a gap is provided between the housing and the flow path.

11. The cooling structure according to claim 1, wherein
the flow path does not overlap the housing in a plan view.
